(19) United States
(12) Patent Application Publication
(10) Pub. No.: US 2009/0091375 A1
(43) Pub. Date: Apr. 9, 2009

(54) SYSTEM AND METHOD TO MINIMIZE TRANSITION TIME BETWEEN CIRCUIT OPERATING MODES

(75) Inventors: Carrie Ellen COX, Cary, NC (US); Hayden Clavie CRANFORD, JR., Cary, NC (US); Todd Morgan RASMUS, Cary, NC (US); Steven Mark CLEMENTS, Raleigh, NC (US)

Correspondence Address: IBM RP-RPS;SAWYER LAW GROUP LLP, 2465 E. Bayshore Road, Suite No. 406, PALO ALTO, CA, 94303, US

(73) Assignee: INTERNATIONAL BUSINESS MACHINES CORPORATION, Armonk, NY (US)

(21) Appl. No.: 11/866,961

(22) Filed: Oct. 3, 2007

(51) Int. Cl. H03K 3/01

(52) U.S. Cl. 327/534

(57) ABSTRACT

A system is disclosed. The system includes a first circuit, the first circuit includes a bias device for allowing the first circuit to transition between a first mode and a second mode. The system further includes a second circuit which controls the bias device. The second circuit provides a bias voltage at a sub-threshold voltage level to the bias device when the first device is in one of the first and the second mode. The second circuit provides a bias voltage at a threshold voltage level or higher when the first device is in one of the first and the second mode. Accordingly, the transition time between modes of the first circuit is minimized.

### FIELD OF INVENTION

The present invention relates generally to integrated circuits and in particular to a method and system for minimizing the transition time between a circuit's operating modes.

### BACKGROUND OF THE INVENTION

Today, some computer architecture standards are configured such that a system has multiple operating modes. For example, Peripheral Component Interface (PCI) Express requires a normal operating mode and a low-power operating mode, known as electrical idle mode. During the electrical idle mode, a transmitter is required to have the same common-mode voltage as during normal operating mode. In the PCI Express, and other standards, the transmitter is required to be fully functional by meeting the amplitude, jitter, common-mode noise specifications within eight nano-seconds after the transmitter recovers from electrical idle mode.

A conventional solution is to completely turn off the transmitter and use an auxiliary low-power transmitter to set the common-mode voltage. This solution may be viable when it is possible to quickly turn the transmitter on and off. For example, the transmitter can be turned on and off quickly by turning off the data device. However, to turn off the data device completely, a bias voltage on the transmitter must be set to the appropriate power supply (zero volts for an NFET device). This approach is not feasible within some platforms that require a quick transition between operating modes. A large voltage excursion on the driver outputs can occur when the main driver is turned off while the auxiliary driver is turned on. For a low drive-strength auxiliary driver, the resulting voltage excursion can be impossible to overcome such that the required common-mode voltage is achieved within the specified time frame. Additionally, where the output amplitude requirement is large, a large power supply is required for the transmitter. To operate at high voltages, high-threshold devices are normally used. However, high-threshold devices are not suited for the task because high-threshold devices are slow transistors. Thus, regular, low-threshold devices are used. Accordingly, the voltage across the devices must be carefully handled such that the power supply is never seen across these devices. Thus, placing zero volts on an NFET differential pair gates is not possible. This also applies to PFET devices.

Another approach is to reduce the bias voltage just enough to turn off the transmitter and allow the data device to remain on. In addition, an auxiliary low-power transmitter is used to set the common-mode voltage. This approach is limited because when the bias voltage of the bias device is not zero, some leakage current is present. As a result, leakage current may cause an offset in the transmitter common-mode voltage. As one requirement of a multi-operating mode system is to have the same common-mode voltage during normal operating mode and electrical idle mode, only very small amounts of leakage relative to the auxiliary transmitter drive strength are acceptable. If the amount of power allowed in electrical idle mode is set, then it may not be possible to meet both the recovery time and the electrical idle mode voltage requirements.

An additional approach is to change the reference used to generate the bias voltage. Some multi-operating mode systems require a relatively accurate transmitter amplitude (+/−20%). Accurate amplitude generation generally requires a feedback system to set the bias voltage. However, the speed of the feedback system may be limited due to the stability issue of feedback loops. Thus, a feedback network will typically not be able to meet the recovery time requirements.

Thus, what is needed is a method for minimizing the transition time between a circuit's operating modes. The present invention addresses such a need.

### SUMMARY OF THE INVENTION

A system is disclosed. The system includes a first circuit, the first circuit includes a bias device for allowing the first circuit to transition between a first mode and a second mode. The system further includes a second circuit which controls the bias device. The second circuit provides a bias voltage at a sub-threshold voltage level to the bias device when the first device is in one of the first and the second mode. The second circuit provides a bias voltage at a threshold voltage level or higher when the first device is in one of the first and the second mode. Accordingly, the transition time between modes of the first circuit is minimized.

### BRIEF DESCRIPTION OF THE DRAWINGS

FIG. 1 shows a current mode logic transmitter.

FIG. 2 shows a control circuit coupled to a current mode logic transmitter.

FIG. 3 shows a series of various operating parameter waveforms of a circuit while the circuit operates in exiting electrical idle mode and entering the normal operating mode.

FIG. 4 shows a series of various operating parameter waveforms of a circuit while the circuit operates in normal operation mode followed by electrical idle mode followed by the normal operating mode.

FIG. 5 shows a flowchart of a method for changing operating modes of a circuit quickly within a system.

### DETAILED DESCRIPTION

The present invention relates generally to integrated circuits and in particular to a method and system for minimizing the transition time between a circuit's operating modes. The following description is presented to enable one having ordinary skill in the art to make and use the embodiment and is provided in the context of a patent application and the generic principles and features described herein will be apparent to those skilled in the art. Thus, the present embodiment is not intended to be limited to the embodiments shown, but is to be accorded the widest scope consistent with the principles and features described herein.

A system and method in accordance with the present invention can be utilized to allow a circuit to transition from one mode to another mode by controlling a bias voltage to the circuit. The circuit can quickly transition utilizing a bias device to receive a bias voltage at a voltage above the threshold voltage level in one mode and receiving a sub-threshold voltage level in another mode. Under normal conditions, a FET bias voltage is set to the appropriate power supply voltage to turn the device off. However, if some leakage current is acceptable, then the FET bias voltage does not need to be entirely discharged to the power supply. Since the voltage difference between the sub-threshold voltage level to the normal bias voltage is less than the difference between the power supply and the normal bias voltage, the circuit recovers to the normal bias voltage level more rapidly. Accordingly, the bias voltage at the sub-threshold voltage level is maintained enough above zero volts or ground such that the circuit can transition between modes more quickly than if the bias voltage was zero volts when the circuit transitioned to the electrical idle mode.

Additionally, the bias device may also be controlled such that a common-mode voltage of the driver is the same while the circuit operates in both the normal operating mode and the electrical idle mode given a much increased load resistance (i.e. a low current, low power mode).

A system and method in accordance with the present invention operates advantageously utilizing a current mode logic (CML) transmitter circuit that has multiple operating modes. Although the present invention will be described herein below in the context of a CML transmitter circuit, many other types of circuits could be utilized and that would be within the spirit and scope of the present invention.

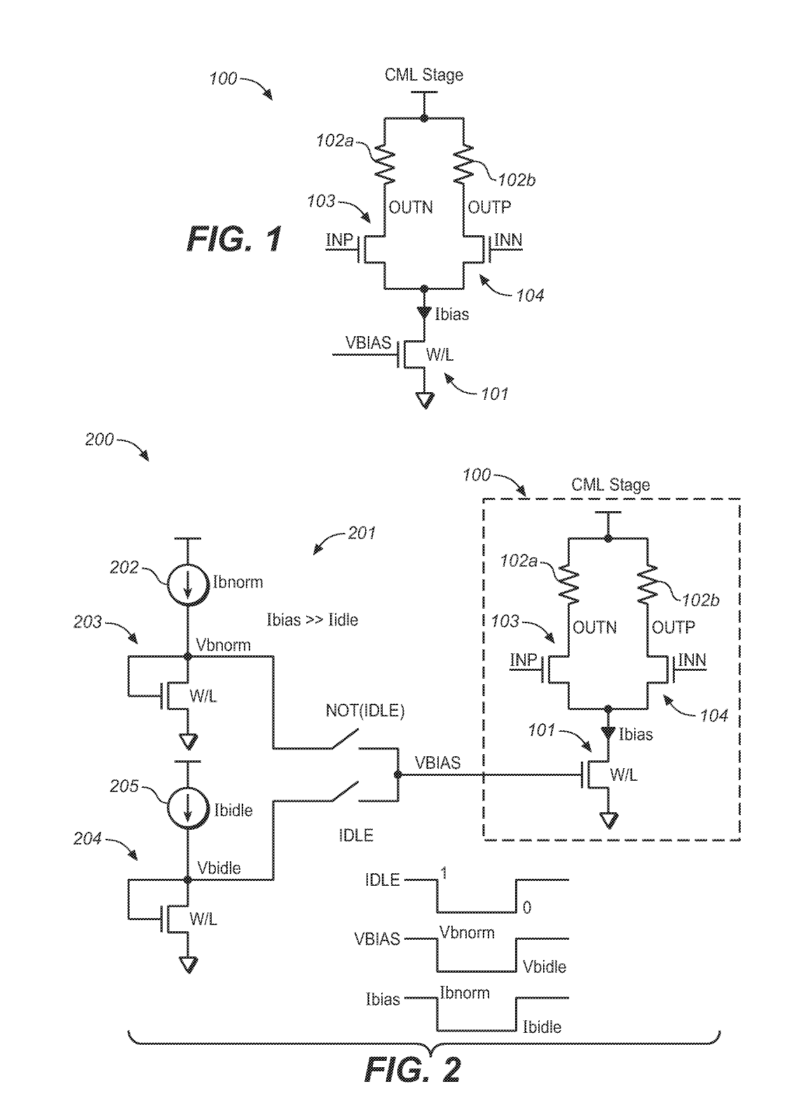

FIG. 1 is an embodiment of a CML transmitter circuit 100. The CML transmitter circuit 100 shown includes one CML buffer stage. In other implementations the CML transmitter circuit 100 includes cascaded CML buffer stages. The CML transmitter circuit 100 includes a field effect transistor (FET) current source 101 and a differential pair 103, 104, wherein each transistor is coupled in series to variable resistive loads 102a, 102b respectively. For the embodiment shown in FIG. 1, FET current source 101 is a bias device (now referred to as bias device 101).

In addition, the bias device 101 receives a bias voltage from a circuit coupled to the CML transmitter circuit 100. The bias device 101 receives a bias voltage that is at either a sub-threshold voltage level when the circuit is in the electrical idle mode or receives a bias voltage that is at or above the threshold voltage level when the circuit is in the normal operating mode to allow for a quicker transition between modes than when utilizing conventional transmitters. To describe this operation in detail, refer now to the following description in conjunction with the accompanying figures.

FIG. 2 shows a system 200 which includes a control circuit 201 for controlling the CML transmitter circuit 100 of FIG. 1. As shown, control circuit 201 includes a plurality of current sources 202, 205 and a plurality of current paths 203, 204. Essentially, the control circuit 201 provides a bias voltage to the gate of the bias device 101 of the CML transmitter circuit 100 that is at a threshold voltage level or higher, via path 203. Alternatively, when the CML transmitter circuit 100 operates in the electrical idle mode, the control circuit 201 provides a bias voltage to the bias device 101 of the CML transmitter circuit 100 that is at a sub-threshold voltage level, via path 204.

As described above, the control circuit 201 provides a bias voltage to the bias device 101 via paths 203, 204. For an embodiment, only one of paths 203, 204 are closed at one time to allow a bias voltage to pass to bias device 101. Thus, when the control circuit 201 provides a bias voltage to the bias device 101 via path 203, only path 203 is closed and path 204 is open, which inhibits a bias voltage from being provided to the bias device 101, via path 204. Alternatively, when the control circuit 201 provides a bias voltage to the bias device 101 via path 204, only path 204 is closed and path 203 is open, which inhibits a bias voltage from being provided to the bias device 101 via path 203.

Additionally, the control circuit 201 can be utilized to quickly transition the CML transmitter circuit 100 from the electrical idle mode to the normal operating mode. As described above, when the CML transmitter circuit 100 is in the electrical idle mode, the CML transmitter circuit 100 operates at a sub-threshold voltage level. Because the sub-threshold voltage level is defined as a voltage maintained enough above zero volts, the CML transmitter circuit 100 transitions to the normal operating mode from the electrical idle mode more quickly than most conventional circuits. For an embodiment, the sub-threshold voltage level for a FET device ranges from Vₜₕ−0.2V and the normal bias level ranges from Vₜₕ+0.2V, where Vₜₕ is the device threshold voltage A typical value of an NFET Vₜₕ in a 90 nm process is 0.4V. Subsequently, if the control circuit 201 provides a bias voltage of 0.2V to the bias device 101 for idle mode, the CML transmitter circuit 100 will transition to the normal operating mode and have bias level 0.6V. Since the voltage excursion is smaller, i.e. 0.4V, than in conventional circuits (i.e. 0V to 0.6V), the CML transmitter circuit 100 can transition more quickly from the electrical idle mode to the normal operating mode.

During the transition between the normal operating mode and the electrical idle mode, the common-mode voltage of the CML transmitter circuit 100 maintains the same voltage level. For an embodiment, the common-mode voltage maintains the same voltage level by varying the impedance of the variable resistive loads 102a, 102b. For example, when the CML transmitter circuit 100 operates in the normal operating mode, the impedance of the variable resistive loads 102a, 102b is approximately 50 ohms. Alternatively, when the CML transmitter circuit 100 operates in the electrical idle mode, the impedance of the variable resistive loads 102, 102b is approximately 2,000 ohms. Accordingly, the impedance of the variable resistive loads 102a, 102b is higher when the CML transmitter circuit 100 operates in the electrical idle mode than when the CML transmitter circuit 100 operates in the normal operating mode.

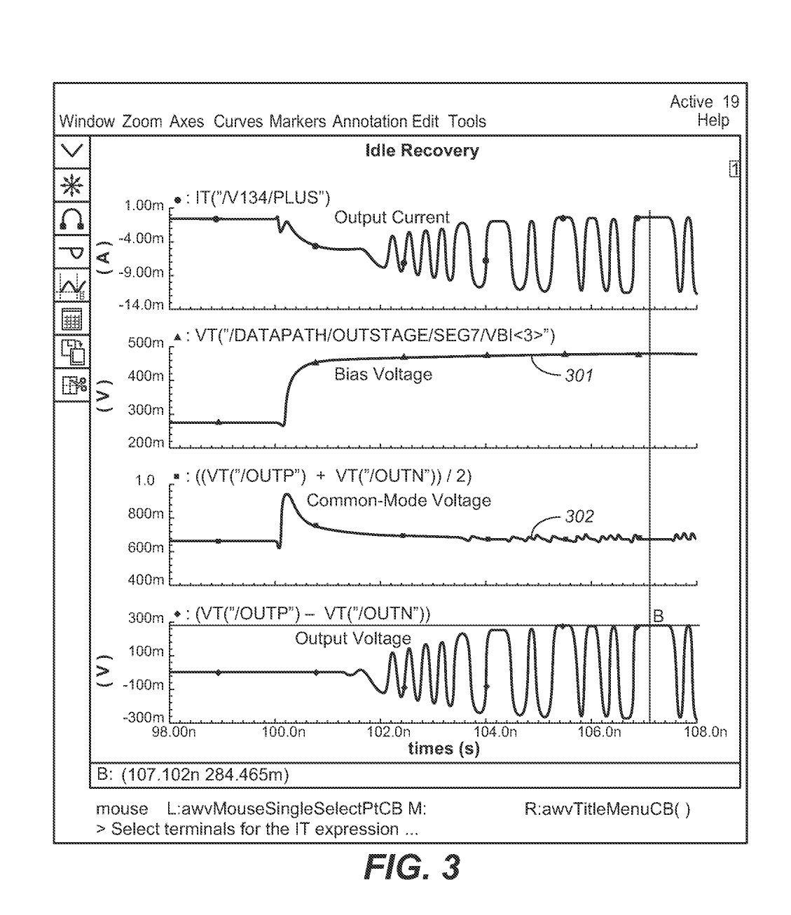

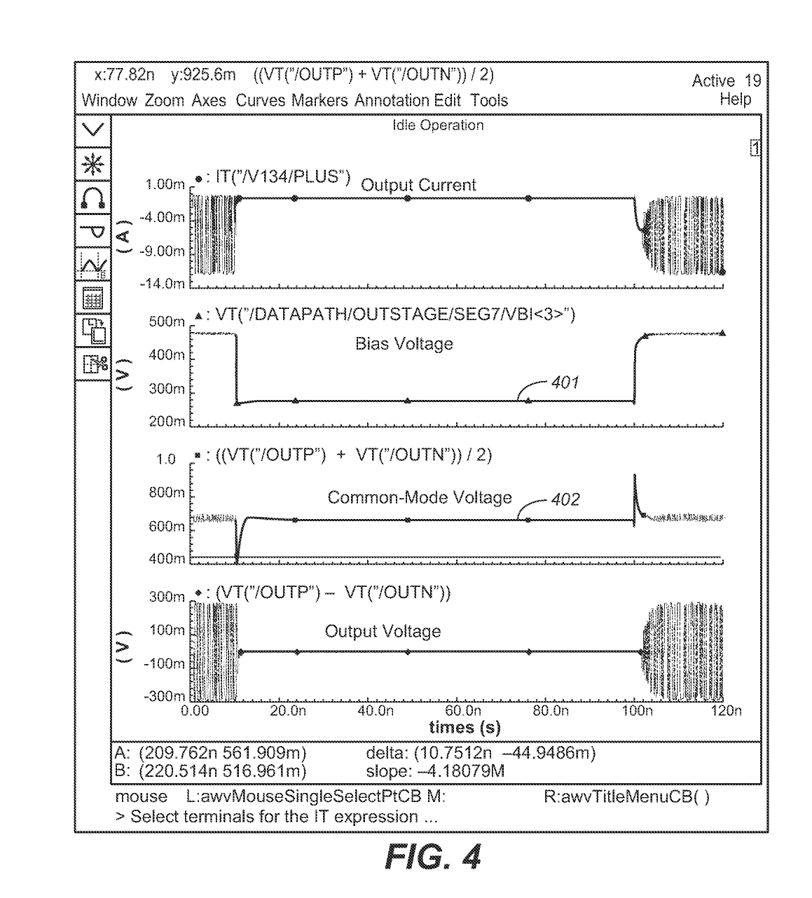

FIGS. 3 and 4 show a series of various operating parameter waveforms of a circuit while operating in the normal operating mode (idle recovery) and the electrical idle mode, respectively. As shown, waveform 301 and 401 shows that the bias voltage is high 450 mV (0.45V) while the CML transmitter circuit 100 operates in the normal operating mode and waveform 401 shows that the bias voltage is low 250 mV (0.25V) while the CML transmitter circuit 100 operates in the electrical idle mode. Waveforms 302 and 402 show that the common-mode voltage maintains the same voltage level 600 mV (0.6V) during the normal operating mode and the electrical idle mode.

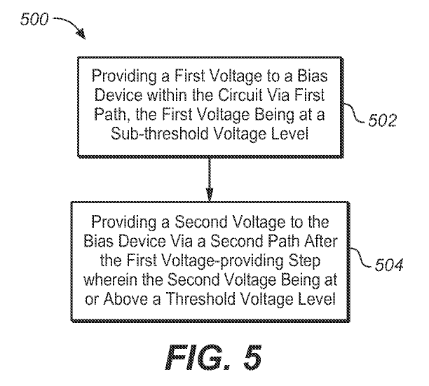

FIG. 5 shows a method, according to flowchart 500, for minimizing the transition time between a circuit's operating modes. As shown in block 502, a first voltage is provided to a bias device within a circuit via a first path. The first voltage is at a sub-threshold voltage level, which enables the circuit to operate in the electrical idle mode. Next, in accordance with block 504, a second voltage is provided to the bias device via a second path after the first voltage is provided. The second voltage enables the circuit to operate in the normal operating mode. For the embodiment, the second voltage is a signal for the circuit to transition the circuit to the normal operating mode. Accordingly, a method of minimizing the transition time between circuit operating modes has been provided.

It is an advantage of a system and method in accordance with the present invention to provide a means for utilizing a bias device for transitioning a circuit between a normal operating mode and an electrical idle mode within a short time period.

It is another advantage to provide a means for controlling a bias voltage of a device such that a common-mode voltage of a device is the same while the circuit operates in both normal electrical idle modes given a much increased load resistance.

It is yet another advantage to limit a change in a bias voltage of a device such that a threshold voltage level can be achieved quickly upon exiting a low power mode.

Although the present embodiment, has been described in accordance with the embodiments shown, one having ordinary skill in the art will readily recognize that there could be variations to the embodiments and those variations would be within the spirit and scope of the present embodiment. For example, although the present invention has been described in the context of a CML transmitter circuit, many other circuits that transition between two or more operating modes via a current source could be utilized and that would be within the spirit and scope of the present invention. Accordingly, many modifications may be made by one having ordinary skill in the art without departing from the spirit and scope of the appended claims.

What is claimed is:

1. A system, comprising:
a first circuit, the first circuit including a bias device for allowing the first circuit to transition between a first mode and a second mode; and
a second circuit which controls the bias device, the second circuit providing a bias voltage at a sub-threshold voltage level to the bias device when the first device is in one of the first and the second mode, and the second circuit providing a bias voltage at a threshold voltage level or higher when the first device is in the other of the first mode and the second mode, wherein the transition time between modes of the first circuit is minimized.

2. The system of claim 1, wherein first circuit comprises at least one common mode logic (CML) transmitter.

3. The system of claim 2, wherein the at least one CML transmitter further comprises cascaded common mode logic buffer stages.

4. The system of claim 3, wherein each common mode logic buffer stage includes a differential transistor pair, wherein each transistor is coupled in series to a resistive load.

5. The system of claim 1, wherein the second circuit is a control circuit.

6. The system of claim 1, wherein the second circuit further comprises a first path and a second path, wherein the second circuit provides a bias voltage at a sub-threshold voltage level to the bias device along one of the first path and the second path or provides a bias voltage at a threshold voltage level or higher to the bias device along the other of the first path and the second path.

7. The system of claim 1, wherein when the bias device receives a bias voltage at the threshold voltage level, the first circuit operates in a normal operating mode and wherein when the bias device receives a bias voltage at the sub-threshold voltage level, the first circuit operates in an electrical idle mode.

8. The system of claim 1, wherein the sub-threshold voltage level range is from 0.2V to 0.65V and the threshold voltage level range is from 0.7V to 0.8V.

9. The system of claim 1, wherein the bias includes a field effect transistor.

10. The system of claim 9, wherein the field effect transistor operates as a current source.

11. A system, comprising:
a current mode logic (CML) transmitter circuit, the current mode logic transmitter circuit including a bias device for allowing the current mode logic transmitter circuit to transition between a normal operating mode and an electrical idle mode; and
a control circuit which controls the bias device, the control circuit providing a bias voltage at a sub-threshold voltage level along a first path to the bias device when the current mode logic transmitter circuit is in the electrical idle mode, and the second circuit providing a bias voltage at a threshold voltage level or higher along a second path to the bias device when the first device is in the normal operating mode, wherein the transition time between modes of the first circuit is minimized.

12. The system of claim 11, wherein the CML transmitter circuit further comprises cascaded common mode logic buffer stages.

13. The system of claim 12, each of the common mode logic buffer stages includes a differential transistor pair, wherein each transistor is coupled in series to a resistive load.

14. The system of claim 11, wherein the first path and the second path each includes a current source and a transistor.

15. The system of claim 11, wherein the bias device includes a field effect transistor.

16. The system of claim 15, wherein the field effect transistor operates as current source.

17. A method for allowing a circuit to transition between a first operating mode and a second operating mode, comprising:
providing a first voltage to a bias device within the circuit via a first path, the first voltage being at a sub-threshold voltage level; and
providing a second voltage to the bias device via a second path after the first voltage-providing step wherein the second voltage being at or above a threshold voltage level.

18. The method of claim 17, wherein providing the first voltage to the bias device transitions the circuit to an electrical idle mode.

19. The method of claim 17, wherein providing the second voltage to the bias device after the first voltage-providing step transitions the circuit to an normal operating mode.

20. The method of claim 17, wherein the first voltage and the second voltage is applied to a gate of the bias device.
